(19) United States
(12) Patent Application Publication
(10) Pub. No.: US 2005/0093169 A1
(43) Pub. Date: May 5, 2005

(54) Semiconductor device and method of manufacturing semiconductor device

(75) Inventor: Akihiro Kajita, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/848,063

(22) Filed: May 19, 2004

(30) Foreign Application Priority Data
Nov. 5, 2003 (JP) 2003-375432

(51) Int. Cl. H01L 21/4763; H01L 23/52

(52) U.S. Cl. 257/774; 438/629; 257/700; 257/775; 438/638

(57) ABSTRACT

A semiconductor device comprises a semiconductor substrate; a semiconductor element formed on a surface of said semiconductor substrate; and a stacked film which includes a plurality of interlayer insulating films deposited on said semiconductor substrate, said interlayer insulating films covering said semiconductor element, and which includes a hollow trench formed in a direction perpendicular to the surface of said semiconductor substrate at least in a part of an outer peripheral region of said semiconductor substrate.

### CROSS-REFERENCE TO RELATED APPLICATION

This application is based upon and claims the benefit of priority from the prior Japanese Patent Application No. 2003-375432, filed on Nov. 5, 2003, the entire contents of which are incorporated herein by reference.

### BACKGROUND OF THE INVENTION

1. Field of the Invention

The present invention relates to a semiconductor device and a method of manufacturing a semiconductor device.

2. Related Background Art

In a semiconductor device typified by a high-performance logic LSI, it is necessary to suppress RC delay of a transmission signal in order to realize high-speed operation. To suppress RC delay, wiring resistance has to be reduced and capacitive coupling between wires has to be suppressed.

Conventionally, to reduce wiring resistance, copper has been used as the material of wires. To suppress capacitive coupling between wires, it has been preferable to employ, as the material of an interlayer insulating film between wires, a material having lower dielectric constant (hereinbelow, also called a low-k material) as compared with that of a silicon oxide film. Prior art related to this is disclosed in Japanese Patent Laid-open Publication JP2000-277465 and JP2000-232081.

However, the mechanical strength of the low-k film is lower than that of a silicon oxide film formed by CVD. Therefore, in the case of using the low-k film as the interlayer insulating film, there is a risk that a crack will occur in the interlayer insulating film or peeling of the interlayer insulating film will occur in a dicing process of individualizing a semiconductor wafer into a plurality of semiconductor chips. Such a crack or peeling causes disconnection of a wire or the like.

In particular, as integration and performance of a semiconductor device increase, in recent years, a multilayer interconnection structure is more frequently employed. In the case of using a low-k film as an interlayer insulating film in the multilayer interconnection structure, adhesion between interlayer insulating films is low. Since a number of interlayer insulating films are stacked, the possibility of occurrence of a crack and peeling is high.

To prevent such a crack or peeling in the interlayer insulating film, a method of providing a metal guard ring 3 near the outer peripheral region of a semiconductor chip (between an element formation region 1 and a scribe line 2) as shown in FIG. 12 is considered. The metal guard ring 3 is provided to prevent extension of a crack or peeling of an interlayer insulating film 4 which is caused by a mechanical impact of dicing to the element formation region 1.

This method is effective in the case where the mechanical strength of the interlayer insulating film supporting the metal guard ring is relatively high as with a silicon oxide film. However, in the case where the mechanical strength is low like that of the low-k film, the metal guard ring cannot prevent a crack or peeling of the interlayer insulating film from extending to the element formation region.

Therefore, it is desired to provide a semiconductor chip having a structure in which a crack or peeling of an interlayer insulating film in a dicing process is prevented from occurring in an element formation region and to provide a method of manufacturing the same.

### SUMMARY OF THE INVENTION

A semiconductor device according to an embodiment of the invention comprises a semiconductor substrate; a semiconductor element formed on a surface of said semiconductor substrate; and a stacked film which includes a plurality of interlayer insulating films deposited on said semiconductor substrate, said interlayer insulating films covering said semiconductor element, and which includes a hollow trench formed in a direction perpendicular to the surface of said semiconductor substrate at least in a part of an outer peripheral region of said semiconductor substrate.

A semiconductor device according to another embodiment of the invention comprises a semiconductor substrate; a semiconductor element formed on said semiconductor substrate; and a stacked film which includes a plurality of interlayer insulating films deposited on said semiconductor substrate, so that said interlayer insulating films cover said semiconductor element, each side face of said interlayer insulating films in an outer peripheral region of said semiconductor substrate being projected or recessed in the horizontal direction with respect to the surface of said semiconductor substrate.

A method of manufacturing a semiconductor device according to an embodiment of the invention comprises: forming semiconductor elements in a plurality of semiconductor chip regions in a semiconductor wafer, said semiconductor wafer including the plurality of semiconductor chip regions in which semiconductor elements are to be formed and a dicing region provided between the semiconductor chip regions; depositing a first interlayer insulating film on said semiconductor wafer, the first interlayer insulating film covering said semiconductor element; forming a first trench near an outer peripheral region of each of said plurality of semiconductor chip regions by partially etching said first interlayer insulating film; filling said first trench with a first conductor; depositing a second interlayer insulating film, said second interlayer insulating film covering said first interlayer insulating film and said first conductor; forming a second trench by etching said second interlayer insulating film on said first conductor; filling said second trench with a second conductor; making a hollow in each of said first and second trenches by etching said first conductor in said first trench and said second conductor in said second trench; and dicing said dicing region to individualize said plurality of semiconductor chip regions.

### BRIEF DESCRIPTION OF THE DRAWINGS

FIG. 1 is a flowchart sequentially showing the flow of processes of a method of manufacturing a semiconductor chip according to a first embodiment of the invention;

FIG. 2 shows a cross section in a flow of a semiconductor wafer manufactured by the method of manufacturing a semiconductor chip according to the first embodiment;

FIG. 3 shows a cross section in a flow subsequent to FIG. 2;

FIG. 4 shows a cross section in a flow subsequent to FIG. 3;

FIG. 5 shows a cross section in a flow subsequent to FIG. 4;

FIG. 6 shows a partial cross section in a flow of a semiconductor chip 100 manufactured according to the first embodiment;

FIG. 7 shows a cross section in a flow of a semiconductor wafer manufactured by a method of manufacturing a semiconductor chip according to a second embodiment;

FIG. 8 shows a cross section in a flow subsequent to FIG. 7;

FIG. 9 shows a cross section in a flow subsequent to FIG. 8;

FIG. 10 shows a cross section in a flow subsequent to FIG. 9;

FIG. 11 shows a partial cross section in a flow of a semiconductor chip 200 according to the second embodiment of the invention; and

FIG. 12 is a view showing a semiconductor chip manufactured by a conventional method of manufacturing a semiconductor chip.

### DETAILED DESCRIPTION OF THE INVENTION

Embodiments of the invention will be described hereinbelow with reference to the drawings. The invention is not limited to the embodiments.

In an embodiment of the invention, a semiconductor wafer has a hollow trench in an interlayer insulating film between a guard ring and a scribe line. The hollow trench prevents a crack or peeling in the interlayer insulating film, which occurs when the scribe line is cut by dicing, from extending to an element formation region.

(First Embodiment)

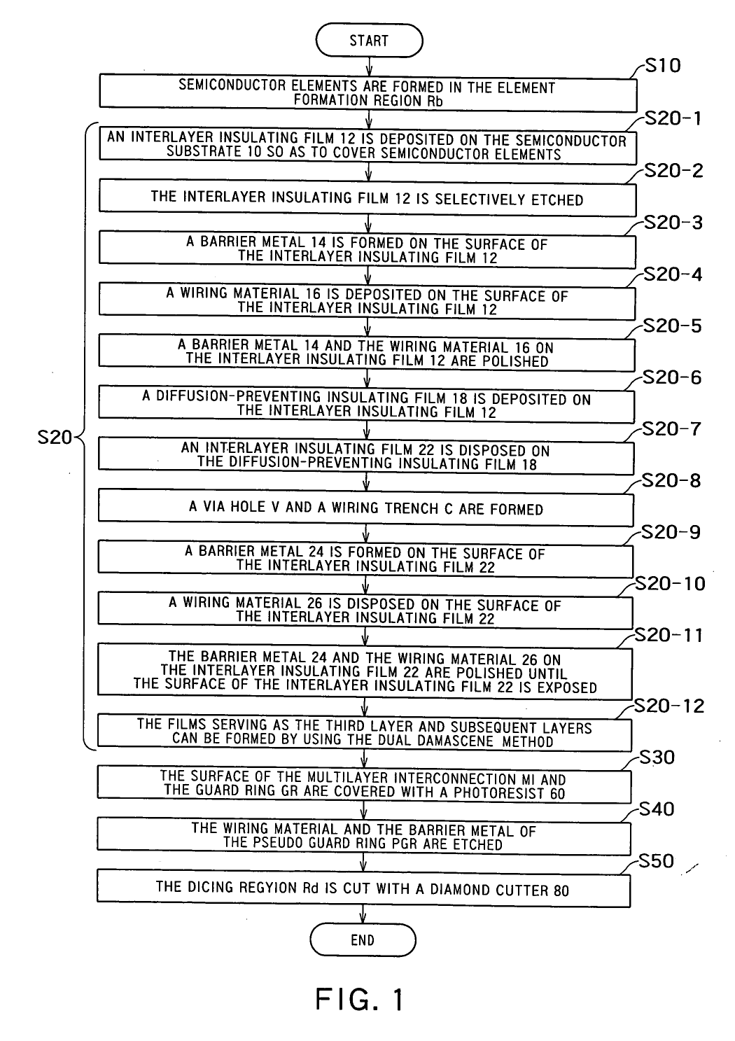

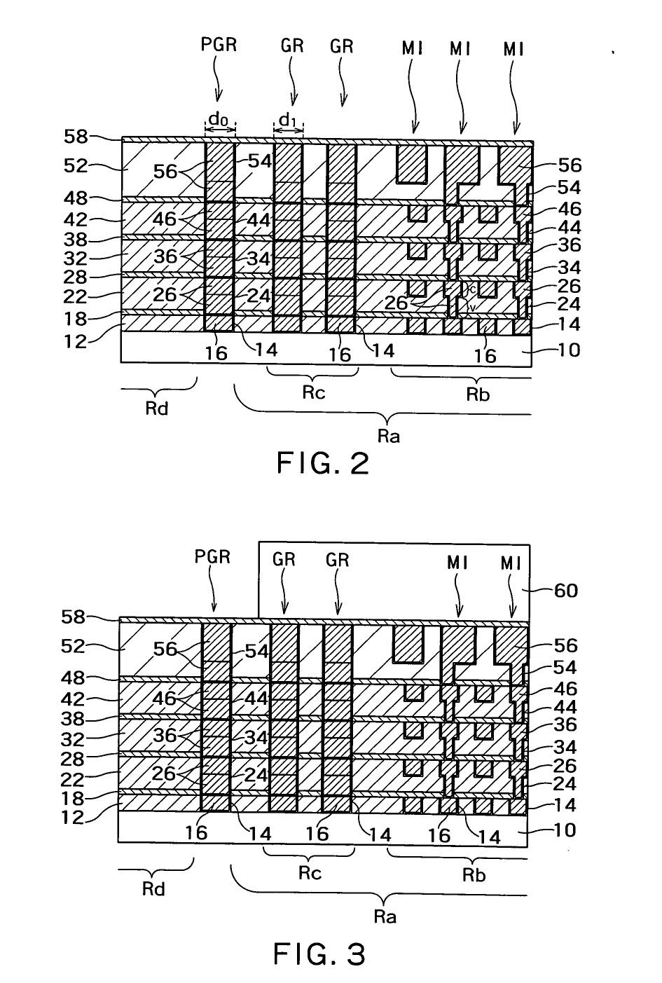

FIG. 1 is a flowchart sequentially showing the flow of processes of a method of manufacturing a semiconductor chip according to a first embodiment of the invention. FIGS. 2 to 5 show a flow of a method of manufacturing a semiconductor chip according to the first embodiment by cross sectional views of a semiconductor wafer manufactured by the same. Further, FIGS. 2 to 5 are cross sections each showing a boundary area between a semiconductor chip region and a scribe line of the semiconductor wafer. Refer to FIG. 1 for steps of the embodiment and refer to FIGS. 2 to 5 for the components of the embodiment.

Referring to FIG. 2, a surface region of a semiconductor substrate 10 will be described. A semiconductor element (not shown) is formed in an element formation region Rb. Around the element formation region Rb, a guard ring formation region Rc is provided so as to surround a semiconductor element region. The element formation region Rb and the guard ring formation region Rc are included in a semiconductor chip region Ra which becomes a semiconductor chip in a post-processing in the semiconductor manufacture. Around the semiconductor chip region Ra, a scribe line, in which a test pattern or the like is formed, is provided. A region in which the scribe line is formed is diced with a diamond cutter in a dicing process of individualizing the semiconductor wafer into semiconductor chips. Therefore, the region is also called a dicing region Rd.

The embodiment will be described with reference to the flowchart of FIG. 1. First, semiconductor elements such as a transistor, a diode or the like are formed in the element formation region Rb (S10).

Next, a multilayer interconnection MI is formed on the element formation region Rb (S20). For example, by repeatedly using the damascene method or dual damascene method, the multilayer interconnection MI can be formed. Concurrently with formation of the multilayer interconnection MI, a guard ring GR is formed by using the same material as the material used for the multilayer interconnection MI in the guard ring formation region Rc. Further, concurrently with the formation of the multilayer interconnection MI, a pseudo guard ring PGR is formed between the semiconductor chip region Ra and the dicing region Rd. That is, the pseudo guard ring PGR is formed near the outer peripheral region of the semiconductor chip region Ra. The pseudo guard ring PGR has the same configuration as that of the guard ring GR. Width d₀ of the pseudo guard ring PGR (width in the horizontal direction with respect to the surface of the semiconductor substrate 10) may be different from width d₁ of the guard ring GR.

A process of forming the multilayer interconnection MI, guard ring GR, and pseudo guard ring PGR (step S20) will be described in detail. First, by using CVD or the like, an interlayer insulating film 12 is deposited on the semiconductor substrate 10 so as to cover semiconductor elements (S20-1). The interlayer insulating film 12 is made of, preferably, a low-k material having a dielectric constant of 3 or less such as SiOC, MSX (Methyl-polysiloxane), HSQ (Hydrogen-silsesquioxane), or PAE (Poly(Arylene)ether). Alternately, the interlayer insulating film 12 may be made of a material obtained by decreasing film density of the low-k material (so-called porous low-k material).

Next, the interlayer insulating film 12 is selectively etched by photolithography, RIE (Reactive Ion Etching), or the like (S20-2). A trench for wiring, a trench for the guard ring, and a trench for a pseudo guard ring are, thereby, patterned in the interlayer insulating film 12. A wiring pattern is formed in the element formation region Rb. The pattern of the guard ring is formed in the guard ring formation region Rc. The pattern of the pseudo guard ring is formed between the semiconductor chip region Ra and the dicing region Rd, that is, near the outer peripheral region of the semiconductor chip region Ra.

Next,-by using CVD or the like, a barrier metal 14 is formed on the surface of the interlayer insulating film 12 (S20-3). At this time, the barrier metal 14 is formed also on the bottom faces and side faces of the respective trenches for the wiring, guard ring, and pseudo guard ring. In the embodiment, the barrier metal 14 may be tantalum, tantalum nitride, titanium silicon nitride (TiSiN), or tungsten nitride.

By using CVD, electrolytic plating, or the like, a wiring material 16 is deposited on the surface of the interlayer insulating film 12 (S20-4). At this time, the respective trenches for the wiring, guard ring, and pseudo guard ring are filled with the wiring material 16. In the embodiment, the wiring material 16 is made of copper. The barrier metal 14 serves for preventing copper of the wiring material 16 from diffusing to the semiconductor elements.

Next, by using CMP or the like, the barrier metal 14 and the wiring material 16 on the interlayer insulating film 12 are polished until the surface of the interlayer insulating film 12 is exposed (S20-5). The barrier metal 14 and the wiring material 16 are, therefore, removed from the interlayer insulating film 12 and remain only in the respective trenches for the wiring, guard ring, and pseudo guard ring. In this manner, by using the damascene method, the first layer in the multilayer interconnection is formed.

Next, by using the dual damascene method, a wiring layer as the second layer is formed. By using plasma CVD or the like, a diffusion-preventing insulating film 18 is deposited on the interlayer insulating film 12 (S20-6). The diffusion-preventing insulating film 18 is made of, for example, SiN, SiCN, SiC or the like and prevents diffusion of copper constituting the wiring material 16.

By using CVD or the like, an interlayer insulating film 22 is disposed on the diffusion-preventing insulating film 18 (S20-7). The interlayer insulating film 22 is made of a low-k material similar to the material of the interlayer insulating film 12.

Next, by using photolithography and RIE or the like, a via hole V and a wiring trench C are formed (S20-8). In the multilayer interconnection MI, the via hole V is formed as a hole communicating with the wiring material 16 of the first layer, and the wiring trench C is formed as a trench for interconnection wiring of the second layer. At this time, in the guard ring GR and the pseudo guard ring PGR, a pattern, which is similar to the pattern formed in the interlayer insulating film 12 as the first layer, is formed in the interlayer insulating film 22. Specifically, in the guard ring GR and the pseudo guard ring PGR, the interlayer insulating film 22 on the wiring material 16 and the barrier metal 14 is removed, and the respective trenches for the guard ring GR and the pseudo guard ring PGR are formed along the wiring material 16 and the barrier metal 14.

Subsequently, by using CVD or the like, a barrier metal 24 is formed on the surface of the interlayer insulating film 22 (S20-9). Therefore, the barrier metal 24 is formed on the respective inner walls of the via hole V and the wiring trench C formed in the interlayer insulating film 22. The barrier metal 24 is formed also on the inner walls of the trenches for the guard ring GR and the pseudo guard ring PGR. The barrier metal 24 is made of a material similar to the material of the barrier metal 14.

By using CVD, electrolytic plating, or the like, a wiring material 26 is disposed on the surface of the interlayer insulating film 22 (S20-10). Each of the via hole V and the wiring trench C is filled with the wiring material 26. The trenches for the guard ring GR and the pseudo guard ring PGR are also filled with the wiring material 26. The wiring material 26 is similar to the material of the wiring material 16, so that the action of the wiring material 26 is similar to that of the wiring material 16.

Next, by using CMP or the like, the barrier metal 24 and the wiring material 26 on the interlayer insulating film 22 are polished until the surface of the interlayer insulating film 22 is exposed (S20-11). The barrier metal 24 and the wiring material 26 are removed from the surface of the interlayer insulating film 22 but remain in the via hole V and the wiring trench C. The barrier metal 24 and the wiring material 26 remain also in the trenches for the guard ring GR and the pseudo guard ring PGR. As described above, by using the dual damascene method, the second layer in the multilayer interconnection is formed.

The interlayer insulating films serving as the third layer and subsequent layers can be formed by using the dual damascene method in a manner similar to the second layer (S20-12). Interlayer insulating films 32 and 42 are made of a material similar to that of the interlayer insulating film 12. However, in the embodiment, as an interlayer insulating film 52, to protect the interlayer insulating films 12, 22, 32, and 42 lower than the interlayer insulating film 52, the low-k film is not used, but a silicon oxide film is used. Barrier metals 34, 44, and 54 are made of a material similar to that of the barrier metal 14. Wiring materials 36, 46, and 56 are made of a material similar to that of the wiring material 16. Diffusion-preventing insulating films 28, 38, 48, and 58 are made of a material similar to that of the diffusion-preventing insulating film 18.

In such a manner, in the element formation region Rb, the multilayer interconnection MI is formed. In the guard ring formation region Rc, the guard ring GR in which the wiring material and the barrier metal are alternately stacked is formed. Near the outer peripheral region of the semiconductor chip region Ra, the pseudo guard ring PGR having the same configuration as that of the guard ring GR is formed.

As shown in FIG. 3, after the multilayer interconnection MI, guard ring GR and pseudo guard ring PGR are formed, the surface of the multilayer interconnection MI and the guard ring GR are covered with a photoresist 60 (S30).

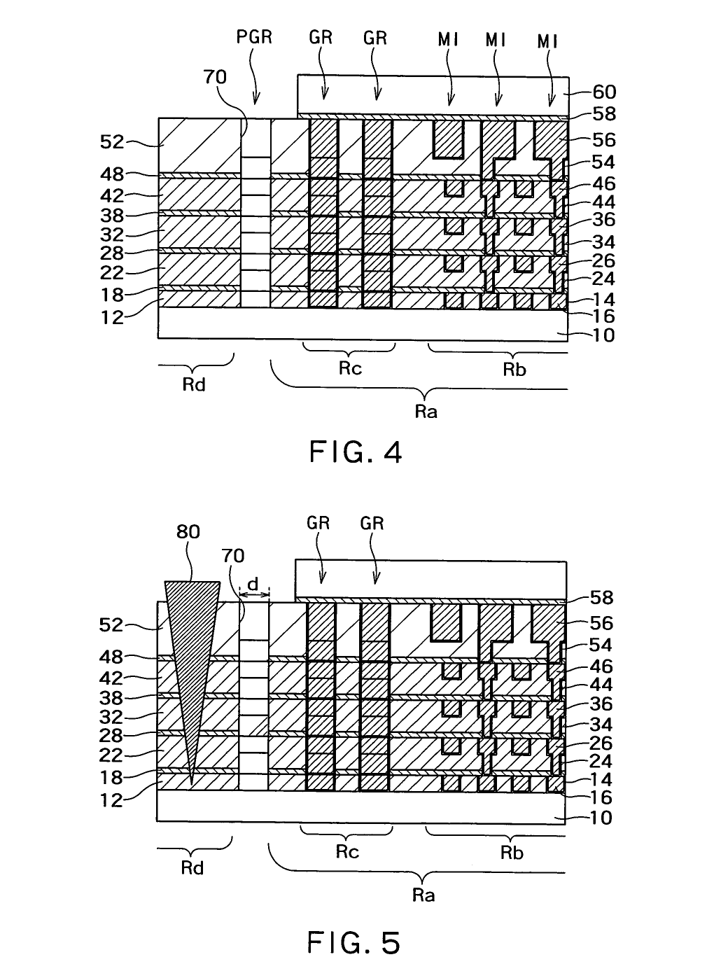

As shown in FIG. 4, then, by using the photoresist as a mask, the wiring material and the barrier metal of the pseudo guard ring PGR are etched (S40). Therefore, a hollow trench 70, which extends from the top face of the uppermost layer 52 of the multilayer interconnection to the bottom face of the lowermost layer 12, is formed in a direction perpendicular to the surface of the semiconductor substrate 10.

In this step S40, first, the diffusion-preventing insulating film 58 is etched. Next, the wiring materials 16, 26, 36, 46, and 56 (hereinbelow, called the wiring materials 16 to 56) and the barrier metals 14, 24, 34, 44, and 54 (hereinbelow, called the barrier metals 14 to 54) are alternately etched.

In the embodiment, the wiring materials 16 to 56 are made of copper. Therefore, the wiring materials 16 to 56 can be etched by using a mixture of hydrochloric acid and hydrogen peroxide solution. Alternatively, a chemical other than the mixture of hydrochloric acid and hydrogen peroxide solution may be used as long as it can etch copper without etching the interlayer insulating films 12, 22, 32, 42, and 52 (hereinbelow, called interlayer insulating films 12 to 52).

In the case where the barrier metals 14 to 54 are made of tantalum, by using CF₄ as an etching gas, dry etching is performed on the barrier metals 14 to 54 by CDE (Chemical Dry Etching). Alternately, the barrier metals 14 to 54 may be subjected to wet etching using a hydrogen fluoride solution. However, the hydrogen fluoride solution also etches the silicon oxide film. Therefore, if any of the interlayer insulating films 12 to 52 is made of a silicon oxide film, a sufficiently large interval has to be provided between the guard ring GR and the pseudo guard ring PGR. Because, in the case where the interlayer insulating film is etched while etching the barrier metals 14 to 54, the hydrogen fluoride solution has to be prevented from reaching the guard ring GR.

In the pseudo guard ring PGR, the wiring materials 16 to 56 made of copper and the barrier metals 14 to 54 made of tantalum are alternately stacked. Therefore, to remove the wiring materials 16 to 56 and the barrier metals 14 to 54, it is necessary to alternately execute etching using the mixture of hydrochloric acid and hydrogen peroxide solution and CDE or to alternately execute etching using the mixture of hydrochloric acid and hydrogen peroxide solution and etching using hydrogen fluoride solution.

Alternatively, the wiring materials 16 to 56 and the barrier metals 14 to 54 may be simultaneously etched by RIE in step S40. In this case, high-temperature RIE using Cl₂ and BCl₃ as etching gas is employed. Therefore, the wiring materials 16 to 56 and the barrier metals 14 to 54 of the pseudo guard ring PGR can be simultaneously removed.

The barrier metals 14 to 54 may be made of tantalum nitride. In this case as well, by using etching similar to that in the case where the barrier metals 14 to 54 are made of tantalum, the wiring materials 16 to 56 and the barrier metals 14 to 54 of the pseudo guard ring PGR can be removed.

One of the barrier metals 14 to 54 may be made of tantalum, the other of barrier metals 14 to 54 may be made of tantalum nitride. In this case as well, by using etching similar to that in the case where the barrier metals 14 to 54 are made of tantalum, the wiring materials 16 to 56 and the barrier metals 14 to 54 of the pseudo guard ring PGR can be removed.

In the case where the barrier metals 14 to 54 are made of titanium silicon nitride (TiSiN), the wiring materials 16 to 56 and the barrier metals 14 to 54 can be removed simultaneously by the mixture of hydrochloric acid and hydrogen peroxide solution. Because the titanium silicon nitride can be etched by the mixture of hydrochloric acid and hydrogen peroxide like copper. Generally, it is difficult to perform dry etching such as RIE on copper but copper can be wet-etched easily at a high rate with the mixture of hydrochloric acid and hydrogen peroxide solution. Therefore, when the barrier metals 14 to 54 are made of titanium silicon nitride, the wiring materials 16 to 56 and the barrier metals 14 to 54 can be removed at a high rate by a single etching process using the mixture of hydrochloric acid and hydrogen peroxide solution.

Also in the case where the barrier metals 14 to 54 are made of tungsten nitride (WN), by using etching similar to that in the case where the barrier metals 14 to 54 are made of titanium silicon nitride, the wiring materials 16 to 56 and the barrier metals 14 to 54 of the pseudo guard ring PGR can be removed.

As described above, the wiring materials 16 to 56 and the barrier metals 14 to 54 can be removed with fewer processes in shorter time in the case where the barrier metals 14 to 54 are made of titanium silicon nitride or tungsten nitride as compared with the case where the barrier metals 14 to 54 are made of tantalum or tantalum nitride.

From the viewpoint of the number of processes and processing time, it is more preferable that the barrier metals 14 to 54 are made of titanium silicon nitride or tungsten nitride rather than tantalum or tantalum nitride.

As shown in FIG. 5, next, the dicing region Rd is cut with a diamond cutter 80 (S50). After the dicing process, individual semiconductor chips are obtained.

By the hollow trench 70, the semiconductor chip region Ra and the dicing region Rd are separated from each other in the multilayer interconnection structure on the semiconductor substrate 10. Therefore, even if a crack or peeling occurs in the multilayer interconnection structure of the dicing region Rd in step S50, the crack or peeling does not extend to the multilayer interconnection structure of the semiconductor chip region Ra. As a result, the reliability of the semiconductor chip can be improved.

In the embodiment, the width “d” of the hollow trench 70 does not have to be specified. To achieve the effect, it is sufficient that the hollow trench 70 separates the multilayer interconnection structure of the semiconductor chip region Ra and the multilayer interconnection structure of the dicing region Rd.

The dielectric constant of the interlayer insulating films 14 to 52 will now be examined. The dielectric constant “k” of the silicon oxide film is 3.5 to 4.3. The dielectric constant “k” of fluorine-doped SiO₂ (FSG) is 3.4 to 3.8. In the case where SiO₂ or FSG is employed for the interlayer insulating films 14 to 52, the above-described problem of the crack or peeling does not occur. However, in the case of employing the low-k material such as SiOC, MSX, HSQ, or PAE for the interlayer insulating films 14 to 52, the problem of the crack or peeling occurs. The dielectric constant “k” of SiOC, MSX, HSQ or PAE is 2.6 to 3.0. That is, in the case of employing the low-k material having a dielectric constant “k” of 3.0 or less for the interlayer insulating films 12, to 52, the effects according to the embodiment can be achieved.

Further, the dielectric constant of a so-called porous low-k material is lower than that of the low-k material. In the case of employing the porous low-k material for the interlayer insulating films 12 to 52, therefore, the RC delay of the multilayer interconnection structure is reduced further. However, since the porous low-k material has a low film density, its mechanical strength is lower than that of a normal low-k material. Therefore, in the case of employing the porous low-k material for the interlayer insulating films 14 to 52, the effects according to the embodiment can be achieved more effectively.

The interlayer insulating films 12 to 42 may be made of different kinds of low-k materials, respectively. For example, the interlayer insulating film 12 may be made of SiOC and the interlayer insulating films 22 to 42 are made of PAE. Also, the lower layer part (via layer) of each of the interlayer insulating films 22 to 42 may be made of SiOC and the upper layer part (wiring layer) may be made of PAE.

In the embodiment, all of the interlayer insulating films 12 to 42 are made of low-k materials. However, when at least one of the layers is made of a low-k material, the effects according to the embodiment can be achieved.

Although two guard rings GR are formed in the embodiment, the number of the guard rings GR may be one or three or more. Although only one pseudo guard ring PGR is formed, two or more pseudo guard rings may be formed.

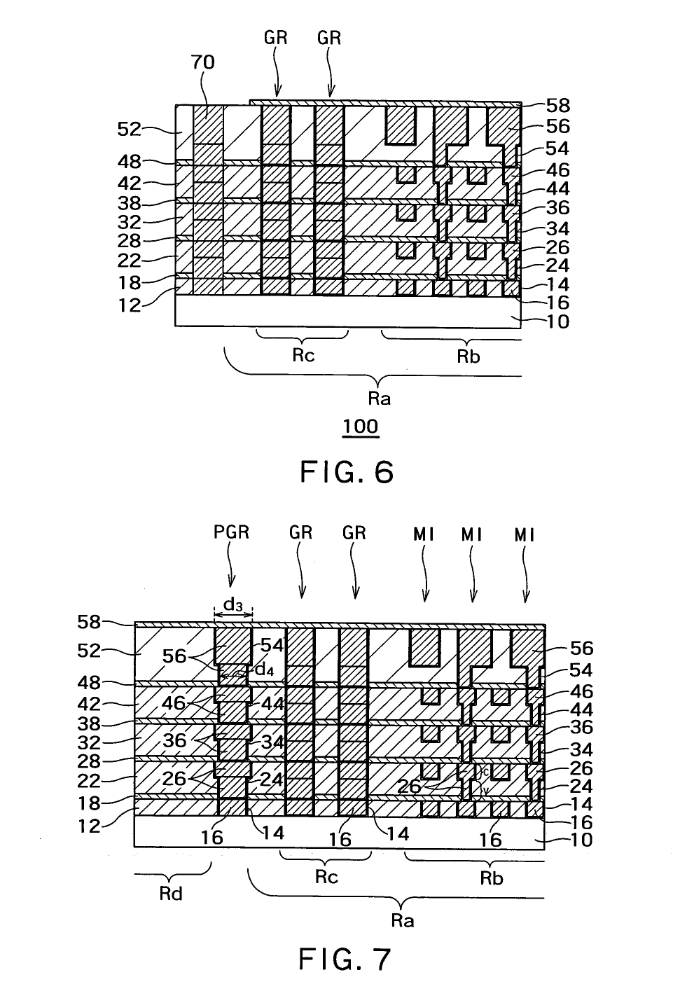

FIG. 6 shows a partial cross section of a semiconductor chip 100 manufactured by the manufacturing method according to the first embodiment. The semiconductor chip 100 has the semiconductor substrate 10, semiconductor elements (not shown) formed on a surface of the semiconductor substrate 10, and a plurality of interlayer insulating films 12 to 52 deposited on the semiconductor substrate 10 so as to cover the semiconductor elements.

The interlayer insulating films 12 to 52 have the hollow trench 70 formed in the direction perpendicular to the surface of the semiconductor substrate 10 in an outer peripheral region of the semiconductor substrate 10. The hollow trench 70 is formed so as to extend from the top face of the uppermost layer 52 to the bottom face of the lowermost layer 12 in the interlayer insulating films 12 to 52.

It is sufficient that the hollow trench 70 remain at least in a part of the outer peripheral region of the semiconductor substrate 10. This is because there is the possibility that a part included in the dicing region Rd on the outside of the hollow trench 70 in the interlayer insulating films 12 to 52 is blown off due to the influence of the dicing process in step S50.

The guard ring GR is formed so as to surround the outside of the element formation region Rb and is provided in the interlayer insulating films 12 to 52 on the center side of the semiconductor substrate 10 with respect to the hollow trench 70. The guard ring GR prevents intrusion of water to the interlayer insulating films 12 to 52 of the element formation region Rb.

As described above, in the semiconductor chip 100 manufactured according to the first embodiment, the hollow trench 70 prevents a crack or peeling which occurs in the dicing region Rd in step S50 from extending to the semiconductor chip region Ra. As a result, the reliability of the semiconductor chip 100 is higher than that of the conventional semiconductor chip.

(Second Embodiment)

FIGS. 7 to 10 show a method of manufacturing a semiconductor chip according to a second embodiment of the invention by cross sectional views of a semiconductor wafer in a flow. Since the flowchart of the method of manufacturing a semiconductor chip according to the second embodiment is similar to that of FIG. 1, it is omitted.

As shown in FIG. 7, in the pseudo guard ring PGR, width d₃ of a wiring trench formation layer and width d₄ of a via hole formation layer are different from each other. With respect to this point, the second embodiment is different from the first embodiment. The other configuration of the second embodiment is similar to that of the first embodiment.

To form the pseudo guard ring PGR in such a form, in step S20-8, it is sufficient to form the pseudo guard ring PGR so as to have the widths d₃ and d₄ similarly for the wiring trench C and the via hole V in the element formation region Rb.

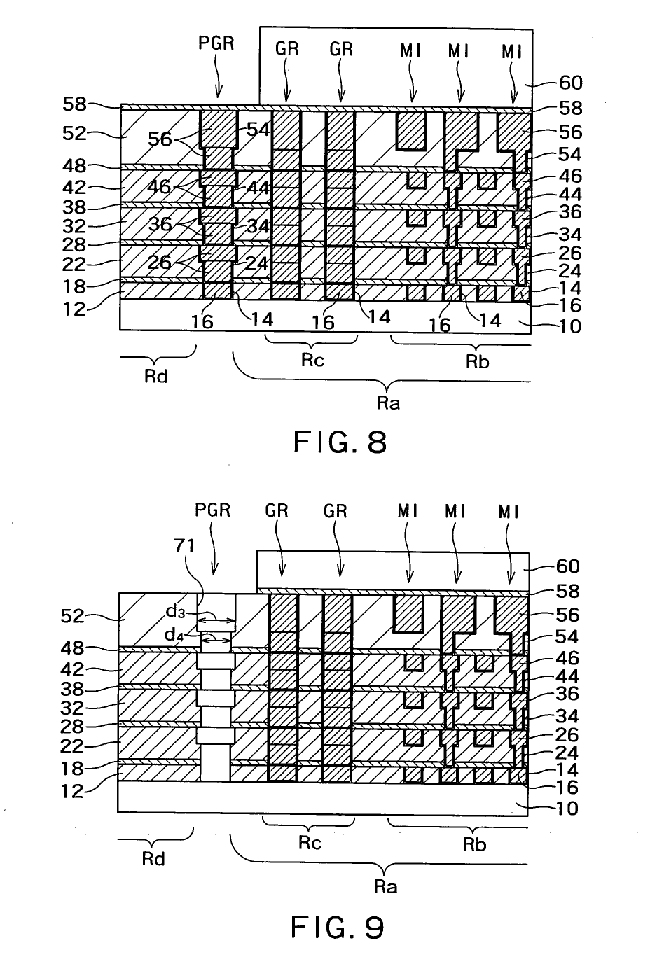

As shown in FIG. 8, next, the photoresist 60 is formed (refer to step S30 in FIG. 1).

As shown in FIG. 9, the wiring materials 16 to 56 and the barrier metals 14 to 54 in the pseudo guard ring PGR are etched (refer to step S40 in FIG. 1). Thereby a hollow trench 71 is formed. Different from the hollow trench 70 in the first embodiment, the hollow trench 71 has projected and recessed side walls.

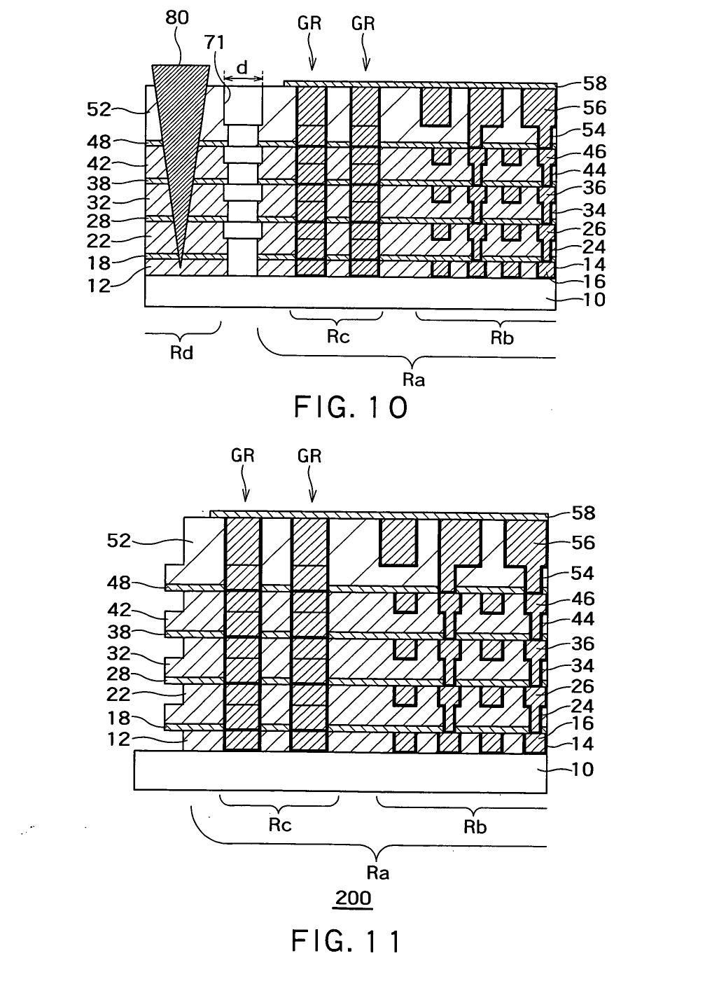

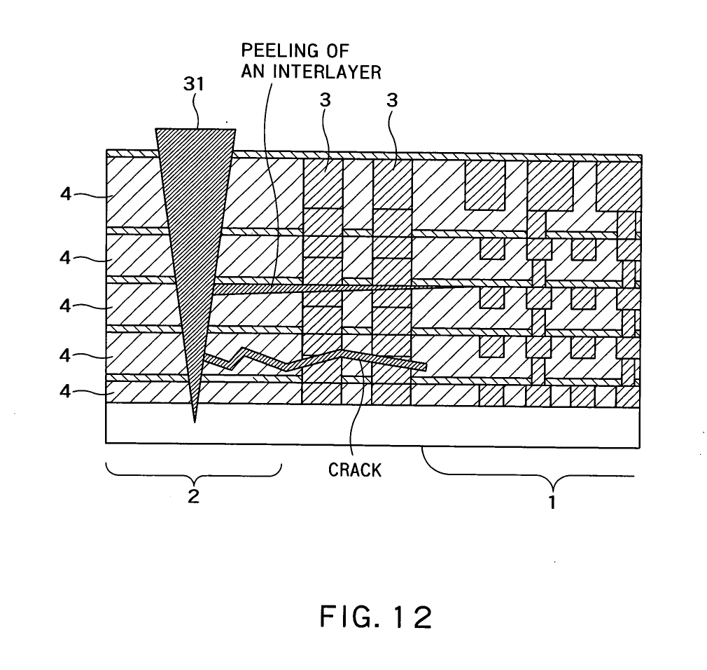

As shown in FIG. 10, the dicing region Rd is cut with the diamond cutter 80 (refer to step S50 in FIG. 1). At this time, the hollow trench 71 has effects similar to those of the hollow trench 70 in the first embodiment.

In the first embodiment, the hollow trench 70 has to remain at least in a part of the outer peripheral region of the semiconductor substrate 10 after the dicing process. However, in the second embodiment, the hollow trench 71 does not have to remain at all in the outer peripheral region of the semiconductor substrate 10 after the dicing process. In other words, all of the part included in the dicing region Rd on the outside of the hollow trench 71, of the interlayer insulating films 12 to 52 may be blown off due to the influence of the dicing process in step S50. The reason will be described with reference to FIG. 11.

FIG. 11 shows a partial cross section of a semiconductor chip 200 according to the second embodiment of the invention. The semiconductor chip 200 is different from the semiconductor chip 100 with respect to the point that the semiconductor chip 200 has regular projected and recessed side faces in the outer peripheral region of the multilayer interconnection structure. The other configurations of the semiconductor chip 200 are similar to those of the semiconductor chip 100. The guard ring GR is formed so as to surround the outside of the element formation region Rb, and is provided in the interlayer insulating films 12 to 52 on the center side of the semiconductor substrate 10 with respect to the outer peripheral region of the semiconductor substrate 10.

In the semiconductor chip 200, each of side faces of the interlayer insulating films in the outer peripheral region of the semiconductor substrate 10 is projected or recessed in the horizontal direction with respect to the surface of the semiconductor substrate 10. Therefore, even if all of the portion on the outside of the hollow trench 71 in the interlayer insulating films 12 to 52 is blown off in the dicing process, it is understood that the hollow trench 71 is formed.

Obviously, after the dicing process, a part or all of the portions on the outside of the hollow trench 71 of the interlayer insulating films 12 to 52 may remain.

1. A semiconductor device comprising:
a semiconductor substrate;
a semiconductor element formed on a surface of said semiconductor substrate; and
a stacked film which includes a plurality of interlayer insulating films deposited on said semiconductor substrate, said interlayer insulating films covering said semiconductor element, and which includes a hollow trench formed in a direction perpendicular to the surface of said semiconductor substrate at least in a part of an outer peripheral region of said semiconductor substrate.

2. A semiconductor device comprising:
a semiconductor substrate;
a semiconductor element formed on said semiconductor substrate; and
a stacked film which includes a plurality of interlayer insulating films deposited on said semiconductor substrate, so that said interlayer insulating films cover said semiconductor element, each side face of said interlayer insulating films in an outer peripheral region of said semiconductor substrate being projected or recessed in the horizontal direction with respect to the surface of said semiconductor substrate.

3. The semiconductor device according to claim 1, wherein said hollow trench is formed so as to extend from the top face of the uppermost layer of said stacked film to the bottom face of the lowermost layer of the stacked film.

4. The semiconductor device according to claim 1, further comprising a guard ring surrounding the outside of a region in which said semiconductor element is formed, and provided in said stacked film on the center side of said semiconductor substrate with respect to said hollow trench.

5. The semiconductor device according to claim 2, further comprising a guard ring surrounding a region in which said semiconductor element is formed, said guard ring being provided in said stacked film on the center side of said semiconductor substrate with respect to the outer peripheral region.

6. The semiconductor device according to claim 4, wherein said guard ring includes a stacked layer which is made of two materials of copper and tantalum, a stacked layer which is made of three materials of copper, tantalum and tantalum nitride, a stacked layer which is made of two materials of copper and titanium silicon nitride (TiSiN), or a stacked layer which is made of two materials of copper and tungsten nitride.

7. The semiconductor device according to claim 5, wherein said guard ring includes a stacked layer which is formed by two materials of copper and tantalum, a stacked layer which is formed by three materials of copper, tantalum and tantalum nitride, a stacked layer which is formed by two materials of copper and titanium silicon nitride (TiSiN), or a stacked layer which is formed by two materials of copper and tungsten nitride.

8. The semiconductor device according to claim 1, wherein a dielectric constant of one of the interlayer insulating films is at most 3.

9. The semiconductor device according to claim 2, wherein a dielectric constant of one of the interlayer insulating films is at most 3.

10. A method of manufacturing a semiconductor device, comprising:
forming semiconductor elements in a plurality of semiconductor chip regions in a semiconductor wafer, said semiconductor wafer including the plurality of semiconductor chip regions in which semiconductor elements are to be formed and a dicing region provided between the semiconductor chip regions;
depositing a first interlayer insulating film on said semiconductor wafer, the first interlayer insulating film covering said semiconductor element;
forming a first trench near an outer peripheral region of each of said plurality of semiconductor chip regions by partially etching said first interlayer insulating film;
filling said first trench with a first conductor;
depositing a second interlayer insulating film, said second interlayer insulating film covering said first interlayer insulating film and said first conductor;
forming a second trench by etching said second interlayer insulating film on said first conductor;
filling said second trench with a second conductor;
making a hollow in each of said first and second trenches by etching said first conductor in said first trench and said second conductor in said second trench; and
dicing said dicing region to individualize said plurality of semiconductor chip regions.

11. The method of manufacturing a semiconductor device according to claim 10, wherein, when each of the first trench and the second trench are formed, a via hall and a trench using for an interconnection are formed in the each semiconductor chip region.

12. The method of manufacturing a semiconductor device according to claim 10, wherein, when the first trench is formed, a third trench is formed near an outer peripheral region of the each semiconductor chip region, said third trench being formed on a center side of the each semiconductor chip region with respect to the first trench,
wherein, when the first conductor is filled, the third trench is filled with the first conductor,
wherein, when the second trench is formed, a fourth trench is formed by etching the second interlayer insulating film on the third conductor,
wherein, when the second conductor is filled, a guard ring is formed by filling the fourth trench with the second conductor, said guard ring protecting the semiconductor elements in the each semiconductor chip region.

13. The method of manufacturing a semiconductor device according to claim 10 further comprising, forming a first barrier layer on an inside wall of the first trench, after forming the first trench, before filling the first conductor, said first barrier layer being made of a different conductor from the first conductor; and
forming a second barrier layer on an inside wall of the second trench, after forming the second trench, before filling the second conductor, said second barrier layer being made of a different conductor from the second conductor.

14. The method of manufacturing a semiconductor device according to claim 10, wherein the first conductor and the second conductor are made of copper.

15. The method of manufacturing a semiconductor device according to claim 13, wherein the first barrier layer and the second barrier layer are made of tantalum, tantalum nitride, titanium silicon nitride (TiSiN) or tungsten nitride.

16. The method of manufacturing a semiconductor device according to claim 13, wherein, during making the hollow in each of said first and second trenches, all of the first conductor, the second conductor, the first barrier layer and the second barrier layer are etched by a mixture of hydrochloric acid and hydrogen peroxide solution.

17. The method of manufacturing a semiconductor device according to claim 10, wherein, one or both of a dielectric constant of the first interlayer film and that of the second interlayer film is at most 3.
